(19) United States
(12) Patent Application Publication
(10) Pub. No.: US 2026/0130009 A1
(43) Pub. Date: May 7, 2026

(54) DISPLAY APPARATUS AND METHOD OF MANUFACTURING THE SAME

(71) Applicant: Samsung Display Co., Ltd., Yongin-si (KR)

(72) Inventors: Hyuneok Shin, Yongin-si (KR); Sunghoon Yang, Yongin-si (KR); Inyoung Jung, Yongin-si (KR)

(21) Appl. No.: 19/381,984

(22) Filed: Nov. 6, 2025

(30) Foreign Application Priority Data
Nov. 7, 2024 (KR) 10-2024-0157158

(51) Int. Cl. H10H 20/817; H10H 20/01; H10H 20/84

(52) U.S. Cl. CPC H10H 20/817; H10H 20/0137; H10H 20/84

(57) ABSTRACT

Provided is a display apparatus including a substrate, and an inorganic light-emitting diode provided on the substrate and including a pixel electrode, a first semiconductor layer, an intermediate layer, a second semiconductor layer, and an opposite electrode. The first semiconductor layer includes a seed layer, a first-1 semiconductor layer provided on the seed layer, a first shield layer provided on the first-1 semiconductor layer and including a first opening defined therein, a first-2 semiconductor layer provided on the first shield layer, a second shield layer provided on the first-2 semiconductor layer and including a second opening defined therein, and a first-3 semiconductor layer provided on the second shield layer.

### CROSS-REFERENCE TO RELATED APPLICATION

The present application claims priority to and the benefit of Korean Patent Application No. 10-2024-0157158, filed on Nov. 7, 2024, in the Korean Intellectual Property Office, the entire disclosure of which is incorporated herein by reference.

### BACKGROUND

### 1. Field

One or more aspects of embodiments of the present disclosure are directed toward a display apparatus and a method of manufacturing the display apparatus.

### 2. Description of the Related Art

A display apparatus can visually display data. A display apparatus may be used as a display unit of products such as mobile phones (e.g., relatively small-sized products), and may be used as a display unit of large-scale products (e.g., relatively large-sized products) such as televisions.

A display apparatus includes a plurality of pixels that receive electrical signals and are to emit light based on the received signals and to display images to the outside. Each pixel includes a display element. As an example, an inorganic light-emitting display apparatus includes an inorganic light-emitting diode as a display element.

Recently, as the purpose of a display apparatus has diversified, research on a design to improve the quality of the display apparatus has been ongoing.

### SUMMARY

One or more aspects of embodiments of the present disclosure are directed toward a display apparatus with improved reliability and quality and a method of manufacturing the display apparatus. However, these improved characteristics of the display apparatus are just an example, and the embodiments of the present disclosure are not limited thereto.

Additional aspects will be set forth in part in the description which follows and, in part, will be apparent from the description, or may be learned by practice of the presented embodiments of the disclosure.

According to one or more embodiments, a display apparatus includes a substrate, and an inorganic light-emitting diode provided on the substrate and including a pixel electrode, a first semiconductor layer, an intermediate layer, a second semiconductor layer, and an opposite electrode, wherein the first semiconductor layer includes a seed layer, a first-1 semiconductor layer provided on the seed layer, a first shield layer provided on the first-1 semiconductor layer and including a first opening defined therein, a first-2 semiconductor layer provided on the first shield layer, a second shield layer provided on the first-2 semiconductor layer and including a second opening defined therein, and a first-3 semiconductor layer provided on the second shield layer.

According to one or more embodiments, the first-1 semiconductor layer may include a polycrystalline semiconductor material.

According to one or more embodiments, the first-2 semiconductor layer may include a semiconductor material of a quasi-single crystal.

According to one or more embodiments, the first-3 semiconductor layer may include a semiconductor material of a single crystal or a semiconductor material of a quasi-single crystal.

According to one or more embodiments, the first shield layer may include an inorganic insulating material.

According to one or more embodiments, the first shield layer may include at least one selected from among silicon oxide (SiOₓ), silicon oxynitride (SiON), and silicon nitride (SiNₓ).

According to one or more embodiments, the second shield layer may include a transparent conductive oxide (TCO).

According to one or more embodiments, the seed layer may include a material having a lattice constant similar to a lattice constant of a semiconductor material included in the first-1 semiconductor layer.

According to one or more embodiments, the first-1 semiconductor layer may include gallium nitride (GaN), and the seed layer may include zinc oxide (ZnOₓ).

According to one or more embodiments, the intermediate layer may be provided on the first semiconductor layer.

According to one or more embodiments, the second semiconductor layer may be provided on the intermediate layer.

According to one or more embodiments, a method of manufacturing a display apparatus includes forming a seed layer on a pixel electrode, forming a first-1 semiconductor layer on the seed layer through crystal growth, forming, on the first-1 semiconductor layer, a first shield layer including a first opening defined therein, forming a first-2 semiconductor layer on the first shield layer through crystal growth, forming, on the first-2 semiconductor layer, a second shield layer including a second opening defined therein, and forming a first-3 semiconductor layer on the second shield layer through crystal growth.

According to one or more embodiments, the first-1 semiconductor layer may include a polycrystalline semiconductor material.

According to one or more embodiments, the first-2 semiconductor layer may include a semiconductor material of a quasi-single crystal.

According to one or more embodiments, the first-3 semiconductor layer may include a semiconductor material of a single crystal or a semiconductor material of quasi-single crystal.

According to one or more embodiments, the first shield layer may include an inorganic insulating material.

According to one or more embodiments, the first shield layer may include at least one selected from among silicon oxide (SiOₓ), silicon oxynitride (SiON), and silicon nitride (SiNₓ).

According to one or more embodiments, the second shield layer may include a transparent conductive oxide (TCO).

According to one or more embodiments, the seed layer may include a material having a lattice constant similar to a lattice constant of a semiconductor material included in the first-1 semiconductor layer.

According to one or more embodiments, the first-1 semiconductor layer may include gallium nitride (GaN), and the seed layer may include zinc oxide (ZnOₓ).

According to one or more embodiments, an electronic apparatus includes the display apparatus according to the present embodiments.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to one or more embodiments;

FIG. 2 is a schematic equivalent circuit diagram of a sub-pixel circuit of a display apparatus according to one or more embodiments;

FIG. 3 is a schematic cross-sectional view of a display apparatus according to one or more embodiments; and

FIGS. 4-10 are each a schematic cross-sectional view showing one or more acts of a method of manufacturing a display apparatus according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described in more detail herein below, by referring to the drawings, to explain aspects of the present description.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, the expressions “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, certain embodiments will be illustrated in the drawings and described in the written description. Effects and features of the disclosure, and methods for achieving them will be clarified with reference to one or more embodiments described below in more detail with reference to the drawings. However, the disclosure is not limited to the following embodiments and may be embodied in one or more suitable forms.

Hereinafter, embodiments will be described with reference to the accompanying drawings, wherein like reference numerals refer to like elements throughout, and duplicative descriptions thereof may not be provided.

While such terms as “first” and “second” may be used to describe one or more suitable elements, such elements must not be limited to the above terms. The above terms are used to distinguish one element from another. Thus, a first element could be termed a second element without departing from the teachings of the present invention. Similarly, a second element could be termed a first element.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be further understood that, when a layer, region, or element is referred to as being “on” another layer, region, and/or element, it can be directly or indirectly on the other layer, region, and/or element. For example, intervening layers, regions, and/or elements may be present. By way of contrast, when an element is referred to as being “directly on,” “directly connected to,” or “directly coupled to” another element, there are no intervening elements present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be concurrently (e.g., simultaneously) performed substantially and performed in the opposite order.

In the present specification, “A and/or B” refers to A or B, or A and B. In the present specification, “at least one of A and/or B” refers to A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The x-axis, the y-axis and the z-axis are not limited to three axes of the rectangular coordinate system, and may be interpreted in a broader sense. For example, the x-axis, the y-axis, and the z-axis may be perpendicular (or substantially perpendicular) to one another, or may represent different orientations that are not perpendicular to one another.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

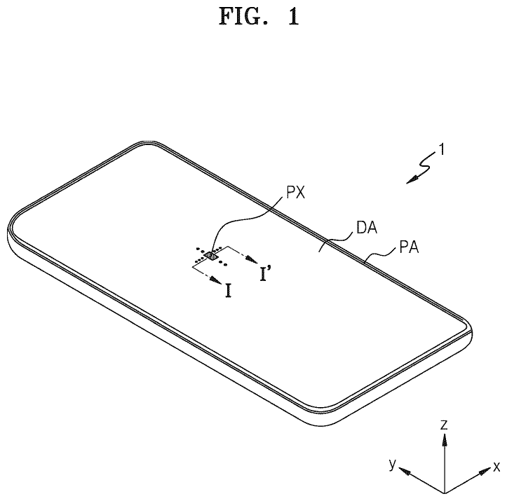

FIG. 1 is a schematic perspective view of a display apparatus 1 according to one or more embodiments.

The display apparatus 1 according to one or more embodiments may be used as a display screen of one or more suitable products including televisions, notebook computers, monitors, advertisement boards, Internet of things (IoTs), as well as portable electronic apparatuses including mobile phones, smartphones, tablet personal computers (PCs), mobile communication terminals, electronic organizers, electronic books, portable multimedia players (PMPs), navigations, and/or ultra mobile personal computers (UMPCs). In one or more embodiments, the display apparatus according to one or more embodiments may be used in wearable devices including smartwatches, watchphones, glasses-type or kind displays, and/or head-mounted displays (HMD). In one or more embodiments, the display apparatus 1 may be used in instrument panels for automobiles, center fascias for automobiles, and/or center information displays (CID) provided on a dashboard, room mirror displays that replace (or complement) side mirrors of automobiles, and/or displays provided on the backside of front seats as entertainment for back seat passengers of automobiles.

Referring to FIG. 1, the display apparatus 1 may have an edge in (e.g., a side extending in) a first direction and an edge in (e.g., a side extending in) a second direction. Here, the first direction and the second direction may be directions crossing each other. As an example, the first direction may form an acute angle with respect to the second direction. In some embodiments, the first direction may form an obtuse angle with respect to the second direction or be perpendicular to the second direction. Hereinafter, the case where the first direction is perpendicular (or substantially perpendicular) to the second direction is mainly described in more detail. As an example, the first direction may be an x direction or a −x direction, and the second direction may be a y direction or a −y direction. A third direction perpendicular to the first direction and the second direction may be a z direction or a −z direction.

The display apparatus 1 may include a display area DA and a peripheral area PA outside the display area DA. The display apparatus 1 may be configured to display images by using light emitted from a plurality of sub-pixels PX provided in the display area DA. The peripheral area PA is a region provided outside the display area DA and may be a kind of non-display area in which sub-pixels are not provided. The display area DA may be surrounded by the peripheral area PA entirely.

Hereinafter, an inorganic light-emitting display and/or an inorganic display apparatus is described as an example of the display apparatus according to one or more embodiments.

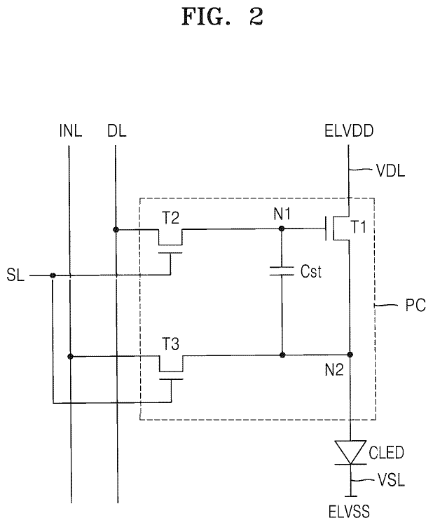

FIG. 2 is a schematic equivalent circuit diagram of a sub-pixel circuit PC of the display apparatus 1 according to one or more embodiments.

Referring to FIG. 2, the sub-pixel circuit PC may include a plurality of transistors and at least one capacitor. In one or more embodiments, the sub-pixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor thin-film transistor including a semiconductor layer that includes an oxide semiconductor, or may be a silicon semiconductor thin-film transistor including a semiconductor that includes polycrystalline silicon. Each thin-film transistor may include a first electrode and a second electrode. Depending on the type or kind of a thin-film transistor, the first electrode may be one of a source electrode or a drain electrode, and the second electrode may be the other of the source electrode or the drain electrode. In one or more embodiments, each thin-film transistor may include a gate electrode.

The first thin-film transistor T1 may be a driving thin-film transistor. The first electrode of the first thin-film transistor T1 may be connected to a driving voltage line VDL configured to supply a driving power voltage ELVDD, and the second electrode may be connected to a pixel electrode of an organic light-emitting diode OLED. The gate electrode of the first thin-film transistor T1 may be connected to a first node N1. The first thin-film transistor T1 may be configured to control the amount of current flowing from the driving power voltage ELVDD to the organic light-emitting diode OLED according to a voltage of the first node N1.

The second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. When a scan signal is supplied through the scan line SL, the second thin-film transistor T2 may be turned on to electrically connect the data line DL to the first node N1.

The third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to an initialization voltage line INL. A gate electrode of the third thin-film transistor T3 may be connected to the scan line SL.

When a scan signal is supplied through the scan line SL, the third thin-film transistor T3 may be turned on to electrically connect the initialization voltage line INL to the second node N2. In one or more embodiments, the third thin-film transistor T3 may be turned on according to a signal transferred through the scan line SL, and may initialize the pixel electrode of the organic light-emitting diode OLED to an initialization voltage from the initialization voltage line INL.

In one or more embodiments, if (e.g., when) a scan signal is supplied to the scan line SL, the third thin-film transistor T3 may be turned on to sense characteristic information of the organic light-emitting diode OLED. The third thin-film transistor T3 may have both (e.g., simultaneously) a function of the initialization thin-film transistor and a function of a sensing thin-film transistor, or one of the two functions. An initialization operation and a sensing operation of the third thin-film transistor T3 may be individually performed, or may be concurrently (e.g., simultaneously) performed. In the case where the third thin-film transistor T3 has a function of the sensing thin-film transistor, the initialization voltage line INL may be referred to as a sensing line.

The storage capacitor Cst may be connected between the first node N1 and the second node N2. For example, a first capacitor plate of the storage capacitor Cst may be connected to the gate electrode of the first thin-film transistor T1, and a second capacitor plate of the storage capacitor Cst may be connected to the pixel electrode of the organic light-emitting diode OLED.

An opposite electrode of the organic light-emitting diode OLED may be connected to a common voltage line VSL configured to provide a common power voltage ELVSS.

Although it is described with reference to FIG. 2 that the sub-pixel circuit PC includes three thin-film transistors and one storage capacitor, the disclosure is not limited thereto. In some embodiments, the number of thin-film transistors and the number of storage capacitors may be variously suitably changed according to the design of the sub-pixel circuit PC.

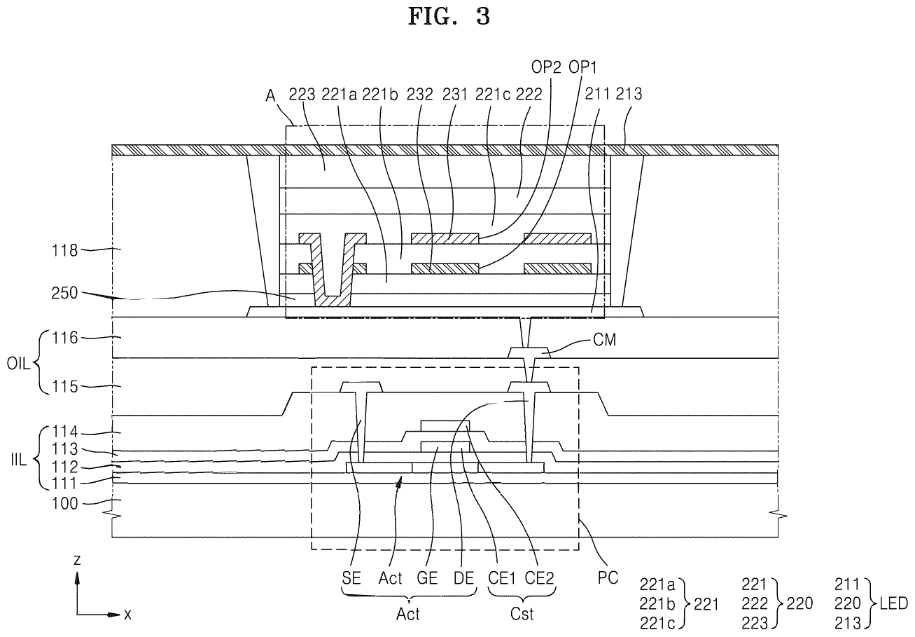

FIG. 3 is a schematic cross-sectional view of the display apparatus 1 according to one or more embodiments.

Referring to FIG. 3, a display panel 10 may include a substrate 100, an inorganic insulating layer IIL, an organic insulating layer OIL, the sub-pixel circuit PC, a connection electrode CM, an inorganic light-emitting diode LED, and a pixel-defining layer 118. For example, the substrate 100, the inorganic insulating layer IIL, the organic insulating layer OIL, the sub-pixel circuit PC, the connection electrode CM, the inorganic light-emitting diode LED, and the pixel-defining layer 118 may be provided in the display area DA of the display panel 10.

In one or more embodiments, the substrate 100 may include a first base layer, a first barrier layer, a second base layer, and a second barrier layer. In one or more embodiments, the first base layer, the first barrier layer, the second base layer, and the second barrier layer may be sequentially stacked in the thickness direction of the substrate 100.

At least one selected from among the first base layer and the second base layer may include a polymer resin including polyethersulfone, polyacrylate, polyetherimide, polyethylene naphthalate, polyethylene terephthalate, polyphenylene sulfide, polyimide, polycarbonate, cellulose tri acetate, and/or cellulose acetate propionate.

The first barrier layer and the second barrier layer are barrier layers configured to prevent or reduce penetration of external foreign materials and may each independently be a single layer or a multi-layer including inorganic materials such as silicon nitride (SiNₓ), silicon oxide (SiO₂), and/or silicon oxynitride (SiON).

The inorganic insulating layer IIL may include a buffer layer 111 that may be provided on the substrate 100. The buffer layer 111 may include an inorganic insulating material such as silicon nitride (SiNₓ), silicon oxynitride (SiON), and/or silicon oxide (SiO₂), and may include a single layer or a multi-layer including the inorganic insulating materials.

Other layers of the inorganic insulating layer IIL may be provided on the buffer layer 111. For example, the inorganic insulating layer IIL may further include a first inorganic insulating layer 112, a second inorganic insulating layer 113, and a third inorganic insulating layer 114.

The sub-pixel circuit PC may be provided in the display area DA. The sub-pixel circuit PC may include a thin-film transistor TFT and the storage capacitor Cst. The thin-film transistor TFT may include a semiconductor layer Act, a gate electrode GE, a source electrode SE, and a drain electrode DE.

The semiconductor layer Act may be provided on the buffer layer 111. The semiconductor layer Act may include polycrystalline silicon. In one or more embodiments, the semiconductor layer Act may include amorphous silicon, an oxide semiconductor, and/or an organic semiconductor. The semiconductor layer Act may include a channel region, a drain region, and a source region, the drain region and the source region being on two opposite sides of the channel region.

The gate electrode GE may be provided over the semiconductor layer Act. The gate electrode GE may overlap the channel region. The gate electrode GE may include a low-resistance metal material. The gate electrode GE may include a conductive material including molybdenum (Mo), aluminum (Al), copper (Cu), and/or titanium (Ti) and have a single-layered structure or a multi-layered structure including any of the above materials.

The first inorganic insulating layer 112 may be provided between the semiconductor layer Act and the gate electrode GE. The first inorganic insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second inorganic insulating layer 113 may be provided on the gate electrode GE. The second inorganic insulating layer 113 may cover the gate electrode GE. The second inorganic insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

An upper electrode CE2 of the storage capacitor Cst may be provided on the second inorganic insulating layer 113. The upper electrode CE2 may overlap the gate electrode GE provided therebelow. In this case, the gate electrode GE and the upper electrode CE2 overlapping each other with the second inorganic insulating layer 113 therebetween may constitute the storage capacitor Cst. For example, the gate electrode GE may serve as a lower electrode CE1 of the storage capacitor Cst.

As described above, the storage capacitor Cst may overlap the thin-film transistor TFT. However, the disclosure is not limited thereto. In some embodiments, the storage capacitor Cst may be formed not to overlap the thin-film transistor TFT. For example, the lower electrode CE1 of the capacitor Cst may be an element separated from the gate electrode GE of the thin-film transistor TFT and may be apart from the gate electrode GE of the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including any of the above materials.

The third inorganic insulating layer 114 may be provided on the upper electrode CE2. The third inorganic insulating layer 114 may cover the upper electrode CE2. The third inorganic insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO). The third inorganic insulating layer 114 may include a single layer or a multi-layer including the inorganic insulating material.

The drain electrode DE and the source electrode SE may each be provided on the third inorganic insulating layer 114. Each of the drain electrode DE and the source electrode SE may be connected to the semiconductor layer Act through a contact hole provided in the first inorganic insulating layer 112, the second inorganic insulating layer 113, and the third inorganic insulating layer 114. The drain electrode DE and the source electrode SE may each independently include a material having suitably high conductivity. The drain electrode DE and the source electrode SE may each independently include a conductive material including molybdenum (Mo), aluminum (Al), copper (Cu), and/or titanium (Ti) and may include a single layer or a multi-layer including any of the above materials. In one or more embodiments, the drain electrode DE and the source electrode SE may each have a multi-layered structure of Ti/Al/Ti.

The organic insulating layer OIL may be provided on the inorganic insulating layer IIL. The organic insulating layer OIL may include a first organic insulating layer 115 and a second organic insulating layer 116. Although it is shown in FIG. 2 that two organic insulating layer OIL are provided, the disclosure is not limited thereto. The organic insulating layer OIL may be provided in three or four layers.

The first organic insulating layer 115 may cover the drain electrode DE and the source electrode SE. The first organic insulating layer 115 may include an organic insulating material including a general-purpose polymer such as polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

The connection electrode CM may be provided on the first organic insulating layer 115. In this case, the connection electrode CM may be connected to the drain electrode DE or the source electrode SE through a contact hole of the first organic insulating layer 115. The connection electrode CM may include a material having a suitably high conductivity. The connection electrode CM may include a conductive material including molybdenum (Mo), aluminum (Al), copper (Cu), and/or titanium (Ti) and may have a single-layered structure or a multi-layered structure including any of the above materials. For example, the connection electrode CM may have a multi-layered structure of Ti/Al/Ti.

The second organic insulating layer 116 may be provided on the connection electrode CM. The second organic insulating layer 116 may cover the connection electrode CM. The second organic insulating layer 116 may include the same material as a material of the first organic insulating layer 115 or may include a different material from a material of the first organic insulating layer 115.

A light-emitting diode may be provided on the second organic insulating layer 116. As an example, an inorganic light-emitting diode LED may be provided on the second organic insulating layer 116.

The inorganic light-emitting diode LED may include a pixel electrode 211, an opposite electrode 213, and an emission layer 220 provided therebetween. The emission layer 220 may include a first semiconductor layer 221, a second semiconductor layer 223, and an intermediate layer 222 between the first semiconductor layer 221 and the second semiconductor layer 223. For example, the intermediate layer may be provided on the first semiconductor layer 221, and the second semiconductor layer 223 may be provided on the intermediate layer 222.

The first semiconductor layer 221 may include, for example, a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with a p-type dopant such as Mg, Zn, Ca, Sr, and/or Ba.

The second semiconductor layer 223 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with an n-type dopant such as Si, Ge, and/or Sn. The disclosure is not limited thereto, and in some embodiments, the first semiconductor layer 221 may include an n-type semiconductor layer, and the second semiconductor layer 223 may include a p-type semiconductor layer.

The intermediate layer 222 is a region in which electrons and holes recombine, and when electrons and holes recombine, they transition to a lower energy level and light (e.g., blue light) having a corresponding wavelength may be emitted. The intermediate layer 222 may include, for example, a semiconductor material having a composition formula of InₓAl_{y}Ga_{1-x-y}N (0≤x≤1, 0≤y≤1, 0≤x+y≤1), and may be formed in a single quantum-well structure or a multi quantum-well structure. In one or more embodiments, the intermediate layer 222 may include a quantum-wire structure and/or a quantum-dot structure.

A seed layer 250 may be provided on the pixel electrode 211. A first-1 semiconductor layer 221a may be formed by being crystalized during a low-temperature process based on the seed layer 250. Because the seed layer 250 serves as a seed of the process of crystalizing the first-1 semiconductor layer 221a, the seed layer 250 may include a material having a lattice constant similar to a lattice constant of a semiconductor material of the first-1 semiconductor layer 221a. For example, in the case where the first-1 semiconductor layer 221a includes gallium nitride (GaN), the seed layer 250 may include zinc oxide (ZnOₓ) having a lattice constant similar to a lattice constant of gallium nitride (GaN). A lattice constant a of GaN is 0.3189 and c is 0.5185, and a lattice constant a of ZnOₓ is 0.3252 and c is 0.5213.

Because the first-1 semiconductor layer 221a is formed by being crystalized during a low-temperature process based on the seed layer 250, the first-1 semiconductor layer 221a may include polycrystals. The first-1 semiconductor layer 221a may include a polycrystalline semiconductor material. In the case where the first semiconductor layer 221 includes polycrystals, defects may be present and brightness and reliability of the display apparatus may deteriorate (e.g., may be unsuitably reduced). According to the present embodiments, the first semiconductor layer 221 may include single crystals to improve the brightness and reliability of the display apparatus.

A first shield layer 231 may be provided on the first-1 semiconductor layer 221a. The first shield layer 231 may include an inorganic insulating material. For example, the first shield layer 231 may include at least one selected from among silicon oxide (SiOₓ), silicon oxynitride (SiON), and silicon nitride (SiNₓ).

A first opening OP1 may be defined in the first shield layer 231. The degree to which the first-1 semiconductor layer 221a is exposed may be relatively reduced by the first opening OP1.

The first shield layer 231 may include an inorganic insulating material. Because the first shield layer 231 includes an inorganic insulating material, when forming the first opening OP1 in the first shield layer 231, a dry etching process may be used to make the first opening OP1 relatively or suitably small, thereby significantly reducing the degree to which the first-1 semiconductor layer 221a is exposed.

A first-2 semiconductor layer 221b may be provided on the first-1 semiconductor layer 221a and the first shield layer 231. The first-2 semiconductor layer 221b may be formed by being crystalized based on the first-1 semiconductor layer 221a. The first-2 semiconductor layer 221b may be formed by being crystalized based on the first-1 semiconductor layer 221a that is relatively less exposed (e.g., a suitably small portion of the first-1 semiconductor layer 221a is exposed) by the first shield layer 231. Because the area of the first-1 semiconductor layer 221a acting as a seed is relatively small due to the first opening OP1, the first-2 semiconductor layer 221b may grow into a quasi-single crystal during the crystallization process. For example, the first-2 semiconductor layer 221b may include a quasi-single crystal semiconductor material.

A second shield layer 232 may be provided on the first-2 semiconductor layer 221b. The second shield layer 232 may include a transparent conductive oxide (TCO). At least a portion of the second shield layer 232 may be connected to a pixel electrode. Because the second shield layer 232 includes a TCO, the second shield layer 232 may electrically connect the pixel electrode to a first-3 semiconductor layer 221c. In one or more embodiments, the second shield layer 232 may improve electrical characteristics of the display apparatus by reducing the resistance of an electrode.

A second opening OP2 may be defined in the second shield layer 232. The degree to which the first-2 semiconductor layer 221b is exposed may be relatively reduced by the second opening OP2.

The first-3 semiconductor layer 221c may be provided on the first-2 semiconductor layer 221b and the second shield layer 232. The first-3 semiconductor layer 221c may be formed by being crystalized based on the first-2 semiconductor layer 221b. The first-3 semiconductor layer 221c may be formed by being crystalized based on the first-2 semiconductor layer 221b that is relatively less exposed (e.g., a suitably small portion of the first-2 semiconductor layer 221b is exposed) by the second shield layer 232. Because the area of the first-2 semiconductor layer 221b acting as a seed is relatively small due to the second opening OP2, the first-3 semiconductor layer 221c may grow into a single crystal or a quasi-single crystal during the crystallization process. For example, the first-3 semiconductor layer 221c may include a single crystal or quasi-single crystal semiconductor material.

Because the first-1 semiconductor layer 221a and the first-2 semiconductor layer 221b may be shielded by the first shield layer 231 and the second shield layer 232 and the degree to which the first-1 semiconductor layer 221a and the first-2 semiconductor layer 221b acting as a seed are exposed may be relatively small, the first-3 semiconductor layer 221c, which is formed by being crystallized last (e.g., from among the first-1 to first-3 semiconductor layers), may grow into a single crystal or quasi-crystal. Because the first-3 semiconductor layer 221c with the largest single crystal content (e.g., amount) is electrically connected to the pixel electrode 211 by the second shield layer 232, the brightness and reliability of the display apparatus may be improved.

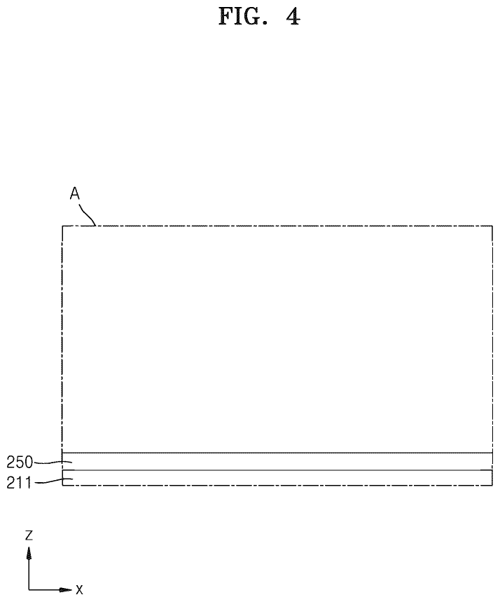

FIGS. 4 to 10 are each a schematic cross-sectional view showing a method of manufacturing the display apparatus 1 according to one or more embodiments.

FIGS. 4 to 10 are each a schematic enlarged cross-sectional view of a region A of FIG. 3, showing a method of manufacturing the display apparatus 1 according to one or more embodiments.

Referring to FIG. 4, the seed layer 250 may be formed on the pixel electrode 211. The seed layer 250 may include a material having a lattice constant similar to a lattice constant of a material of a first-1 semiconductor layer 221a. For example, in the case where the first-1 semiconductor layer 221a includes gallium nitride (GaN), the seed layer 250 may include zinc oxide (ZnOₓ) having a lattice constant similar to a lattice constant of gallium nitride (GaN).

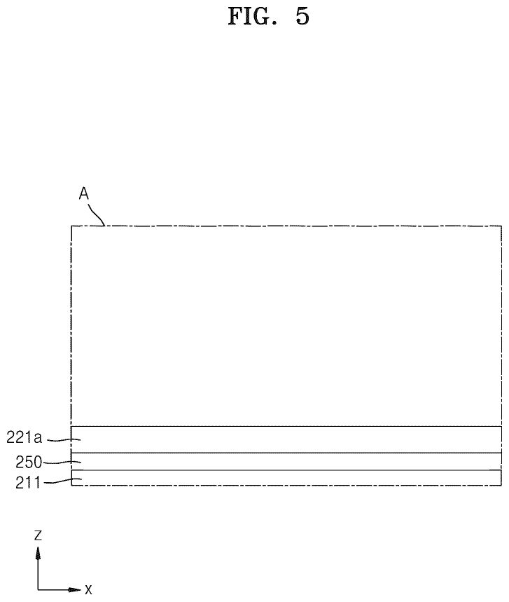

Referring to FIG. 5, the first-1 semiconductor layer 221a may be formed on the seed layer 250 through crystal growth. For example, the first-1 semiconductor layer 221a may be formed by being crystalized based on the seed layer 250. Because the first-1 semiconductor layer 221a is formed by being crystalized during a low-temperature process, the first-1 semiconductor layer 221a may grow into a polycrystal. For example, the first-1 semiconductor layer 221a may include a polycrystalline semiconductor material.

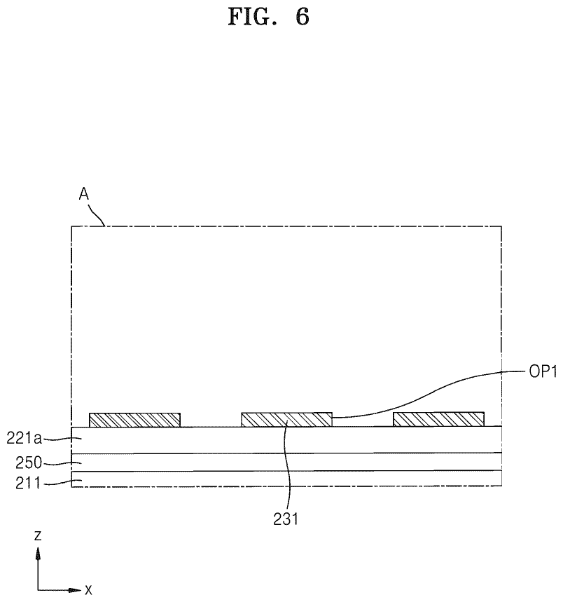

Referring to FIG. 6, the first shield layer 231 in which the first opening OP1 is defined may be formed on the first-1 semiconductor layer 221a. The first shield layer 231 may include an inorganic insulating material. For example, the first shield layer 231 may include at least one selected from among silicon oxide (SiOₓ), silicon oxynitride (SiON), and silicon nitride (SiNₓ). Because the first shield layer 231 includes an inorganic insulating material, a dry etching process may be used during the process of forming the first opening OP1. By making the first opening OP1 relatively or suitably small through the dry etching process, the degree of exposure of the first-1 semiconductor layer 221a acting as a seed may be reduced.

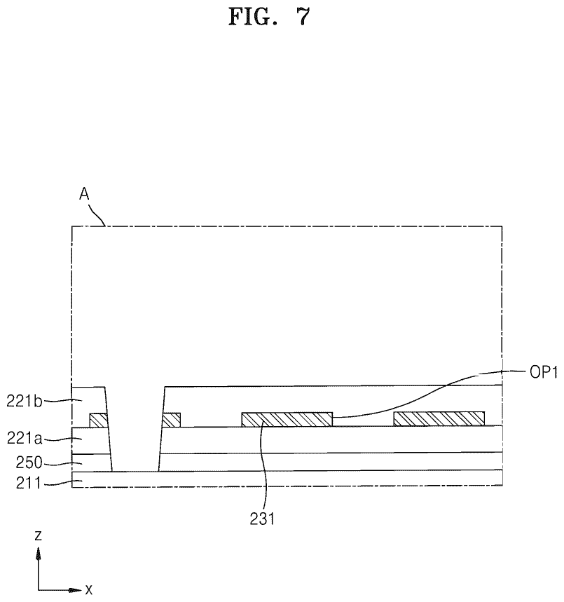

Referring to FIG. 7, the first-2 semiconductor layer 221b may be formed on the first-1 semiconductor layer 221a and the first shield layer 231 through crystal growth based on the first-1 semiconductor layer 221a. Because the first-2 semiconductor layer 221b is formed by being crystalized based on the first-1 semiconductor layer 221a that is relatively less exposed (e.g., only a suitably small portion of the first-1 semiconductor layer 221a is exposed), the first-2 semiconductor layer 221b may grow into a quasi-single crystal. The first-2 semiconductor layer 221b may include a quasi-single crystal semiconductor material.

At least a portion of the seed layer 250, the first-1 semiconductor layer 221a, the first shield layer 231, and the first-2 semiconductor layer 221b may be etched. By etching at least a portion of the seed layer 250, the first-1 semiconductor layer 221a, the first shield layer 231, and the first-2 semiconductor layer 221b, the second shield layer 232 may be provided thereon (e.g., may be provided in the etched portion), wherein the second shield layer 232 is in direct contact with the upper surface of the pixel electrode 211.

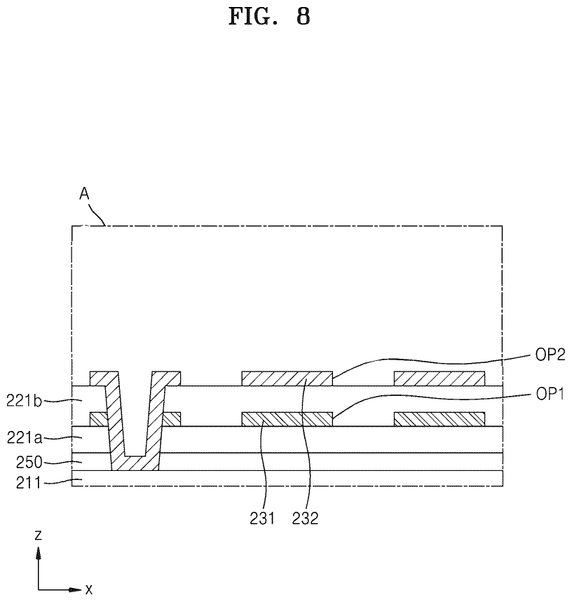

Referring to FIG. 8, the second shield layer 232 in which the second opening OP2 is defined may be formed on the first-2 semiconductor layer 221b. The second shield layer 232 may include a transparent conductive oxide (TCO). The second shield layer 232 may be connected to the pixel electrode 211 to electrically connect the first-3 semiconductor layer 221c, which will be provided thereon, to the pixel electrode 211, and reduce a resistance of the electrode. The degree to which the first-2 semiconductor layer 221b is exposed may be reduced (e.g., may be defined) by the second opening OP2.

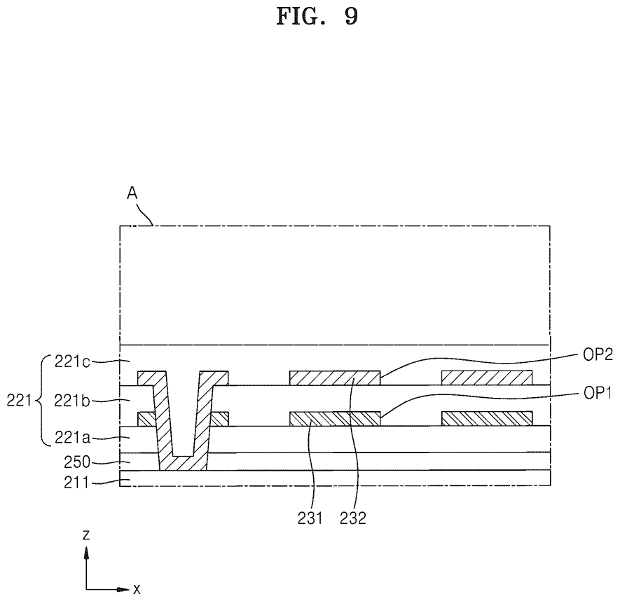

Referring to FIG. 9, the first-3 semiconductor layer 221c may be formed on the second shield layer 232 through crystal growth based on the first-2 semiconductor layer 221b. Because the first-3 semiconductor layer 221c is formed by being crystalized based on the first-2 semiconductor layer 221b that is relatively less exposed (e.g., only a suitably small portion of the first-2 semiconductor layer 221b is exposed), the first-3 semiconductor layer 221c may grow into a single crystal or quasi-single crystal. The first-3 semiconductor layer 221c may include a single crystal or quasi-single crystal semiconductor material.

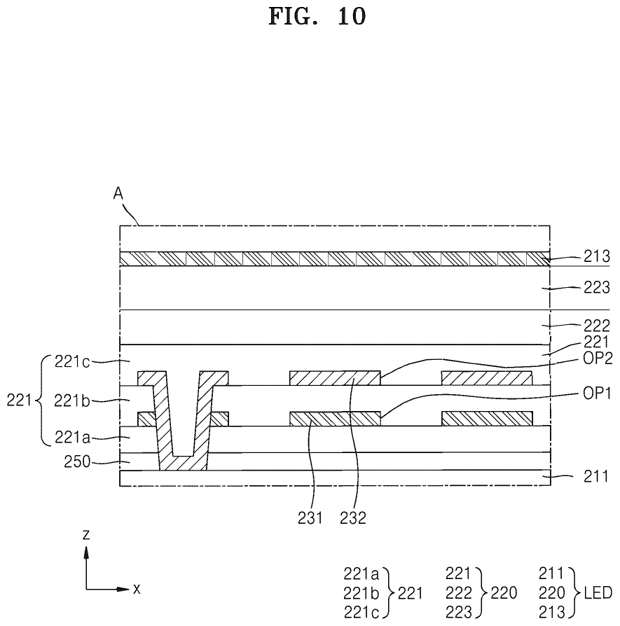

Referring to FIG. 10, the intermediate layer 222, the second semiconductor layer 223, and the opposite electrode 213 may be formed on the first semiconductor layer 221. In some embodiments, the opposite electrode 213 may be continuously formed over the substrate 100.

According to one or more embodiments having the above configuration, the display apparatus with improved reliability and quality may be provided, and the method of manufacturing the display apparatus may be implemented. However, the scope of the disclosure is not limited by this aspect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope of the present disclosure as defined by the following claims and equivalents thereof.

What is claimed is:

1. A display apparatus comprising:
a substrate; and
an inorganic light-emitting diode on the substrate and comprising a pixel electrode, a first semiconductor layer, an intermediate layer, a second semiconductor layer, and an opposite electrode,
wherein the first semiconductor layer comprises:
a seed layer;
a first-1 semiconductor layer on the seed layer;
a first shield layer on the first-1 semiconductor layer and comprising a first opening defined therein;
a first-2 semiconductor layer on the first shield layer;
a second shield layer on the first-2 semiconductor layer and comprising a second opening defined therein; and
a first-3 semiconductor layer on the second shield layer.

2. The display apparatus of claim 1, wherein the first-1 semiconductor layer comprises a polycrystalline semiconductor material.

3. The display apparatus of claim 1, wherein the first-2 semiconductor layer comprises a semiconductor material of a quasi-single crystal.

4. The display apparatus of claim 1, wherein the first-3 semiconductor layer comprises a semiconductor material of a single crystal or a semiconductor material of a quasi-single crystal.

5. The display apparatus of claim 1, wherein the first shield layer comprises an inorganic insulating material.

6. The display apparatus of claim 5, wherein the first shield layer comprises at least one selected from among silicon oxide (SiOₓ), silicon oxynitride (SiON), and silicon nitride (SiNₓ).

7. The display apparatus of claim 1, wherein the second shield layer comprises a transparent conductive oxide (TCO).

8. The display apparatus of claim 1, wherein the seed layer comprises a material having a lattice constant similar to a lattice constant of a semiconductor material included in the first-1 semiconductor layer.

9. The display apparatus of claim 7, wherein the first-1 semiconductor layer comprises gallium nitride (GaN), and the seed layer comprises zinc oxide (ZnOₓ).

10. The display apparatus of claim 1, wherein the intermediate layer is on the first semiconductor layer.

11. The display apparatus of claim 1, wherein the second semiconductor layer is on the intermediate layer.

12. A method of manufacturing a display apparatus, the method comprising:
forming a seed layer on a pixel electrode;
forming a first-1 semiconductor layer on the seed layer through crystal growth;
forming, on the first-1 semiconductor layer, a first shield layer comprising a first opening defined therein;
forming a first-2 semiconductor layer on the first shield layer through crystal growth;
forming, on the first-2 semiconductor layer, a second shield layer comprising a second opening defined therein; and
forming a first-3 semiconductor layer on the second shield layer through crystal growth.

13. The method of claim 12, wherein the first-1 semiconductor layer comprises a polycrystalline semiconductor material.

14. The method of claim 12, wherein the first-2 semiconductor layer comprises a semiconductor material of a quasi-single crystal.

15. The method of claim 12, wherein the first-3 semiconductor layer comprises a semiconductor material of a single crystal or a semiconductor material of quasi-single crystal.

16. The method of claim 12, wherein the first shield layer comprises an inorganic insulating material.

17. The method of claim 12, wherein the first shield layer comprises at least one selected from among silicon oxide (SiOₓ), silicon oxynitride (SiON), and silicon nitride (SiNₓ), and
the second shield layer comprises a transparent conductive oxide (TCO).

18. The method of claim 12, wherein the seed layer comprises a material having a lattice constant similar to a lattice constant of a semiconductor material included in the first-1 semiconductor layer.

19. The method of claim 18, wherein the first-1 semiconductor layer comprises gallium nitride (GaN), and the seed layer comprises zinc oxide (ZnOₓ).

20. An electronic apparatus comprising the display apparatus of claim 1.
